(19) United States
(12) Patent Application Publication
(10) Pub. No.: US 2024/0112954 A1
(43) Pub. Date: Apr. 4, 2024

(54) SELF-ALIGNED CONTACT LANDING ON A METAL CIRCUIT

(71) Applicant: Taiwan Semiconductor Manufacturing Company, Ltd., Hsinchu (TW)

(72) Inventor: Ming-Hsun LIN, Hsinchu City (TW)

(21) Appl. No.: 18/305,708

(22) Filed: Apr. 24, 2023

Related U.S. Application Data
(60) Provisional application No. 63/377,872, filed on Sep. 30, 2022.

(51) Int. Cl. H01L 21/768; H01L 21/8234

(52) U.S. Cl. CPC H01L 21/76897; H01L 21/76895; H01L 21/823431; H01L 21/823475

(57) ABSTRACT

Some implementations described herein include an integrated circuit device including landing circuitry and methods of formation. The landing circuitry, which may be part of a trench capacitor region, includes a stair-shaped profile that extends into a silicon substrate of the integrated circuit device. The landing circuitry includes electrode layers of the trench capacitor region interspersed with layers of a dielectric material. The landing circuitry further includes spacer structures on ends of the electrode layers along the stair-shaped profile.

### CROSS-REFERENCE TO RELATED APPLICATION

This patent application claims priority to Provisional Patent Application No. 63/377,872 filed on Sep. 30, 2022, and entitled “Self-Aligned Contact Landing on a Metal Circuit.” The disclosure of the prior application is considered part of and is incorporated by reference into this patent application.

### BACKGROUND

An integrated circuit (IC) device may include a trench capacitor region, where a multi-layer structure including layers of a conductive material interspersed with layers of a dielectric material conforms to sidewalls of a trench that penetrates vertically into a semiconductor substrate. The trench capacitor region may increase a capacitance of the IC device while preserving area of the IC device for other IC device structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of an example semiconductor structure described herein.

FIGS. 3A-3H are diagrams of an example manufacturing process used to fabricate the semiconductor structure described herein.

FIG. 4 is a diagram of example components of one or more devices of FIG. 1 described herein.

FIG. 5 is a flowchart of an example process associated with fabricating the example semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, advances in process nodes (e.g., patterning through photolithography and etching processes) to reduce a size of an IC device may reduce critical dimensions associated with landing circuitry associated with the trench capacitor region. The reduced critical dimensions may reduce a distance between a connection structure and one or more conductive layers of the landing circuitry. Relative to an IC device fabricated using a previous process node, the reduced distance may increase a likelihood of leakage and/or electrical shorting within the IC device to reduce a performance of the semiconductor device and/or reduce a yield of the semiconductor device.

Some implementations described herein include an IC device including landing circuitry and methods of formation. The landing circuitry, which may be part of a trench capacitor region, includes a stair-shaped profile that extends towards a silicon substrate of the IC device. The landing circuitry includes electrode layers of the trench capacitor region interspersed with layers of a dielectric material. The landing circuitry further includes spacer structures on ends of the electrode layers along the stair-shaped profile.

Including the spacer structures in the landing circuitry of the IC device may reduce a risk of shorting and/or leakage within IC device, which may increase performance of the IC device and/or increase a yield of the IC device. In this way, a risk of shorting and/or leakage, a quality and/or a reliability of the IC device during a field use of the IC device may be improved. Furthermore, and through an increase in a density of the capacitor region, a size of the IC device may be reduced, leading to a reduction in resources (e.g., manufacturing tools, computing resources, and materials) to fabricate a volume of the IC device.

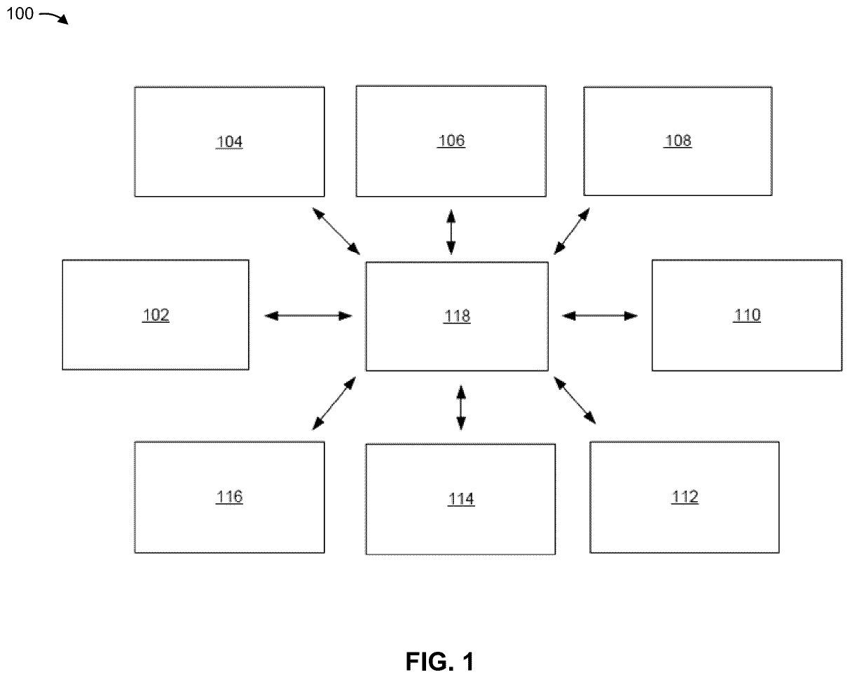

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a develop tool 106, an etch tool 108, a planarization tool 110, a plating tool 112, a pre-treatment tool 114, a plasma tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The develop tool 106 is a semiconductor processing tool that is capable of developing a photoresist layer that has been exposed to a radiation source to develop a pattern transferred to the photoresist layer from the exposure tool 104. In some implementations, the develop tool 106 develops a pattern by removing unexposed portions of a photoresist layer. In some implementations, the develop tool 106 develops a pattern by removing exposed portions of a photoresist layer. In some implementations, the develop tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, a reactive ion etch (RIE) took, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The pre-treatment tool 114 is a semiconductor processing tool that is capable of using various types of wet chemicals, plasma, and/or gasses to treat the surface of one or more layers of a device in preparation for one or more subsequent semiconductor processing operations. For example, the pre-treatment tool 114 may include a chamber in which a device may be placed. The chamber may be filled with a wet chemical, a plasma, and/or a gas that is used to modify the physical and/or chemical properties of one or more layers of a device.

The plasma tool 116 is a semiconductor processing tool, such as a decoupled plasma source (DPS) tool, an inductively coupled plasma (ICP) tool, a transformer coupled plasma (TCP) tool, or another type of plasma-based semiconductor processing tool, that is capable of treating the surface of one or more layers of a device using a plasma. For example, the plasma tool 116 may sputter etch or otherwise remove material from the surface of a layer of a device using plasma ions.

Wafer/die transport tool 118 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-116, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 118 may be a programmed device that is configured to travel a particular path and/or may operate semi-autonomously or autonomously. In some implementations, the environment 100 includes a plurality of wafer/die transport tools 118.

For example, the wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 118 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

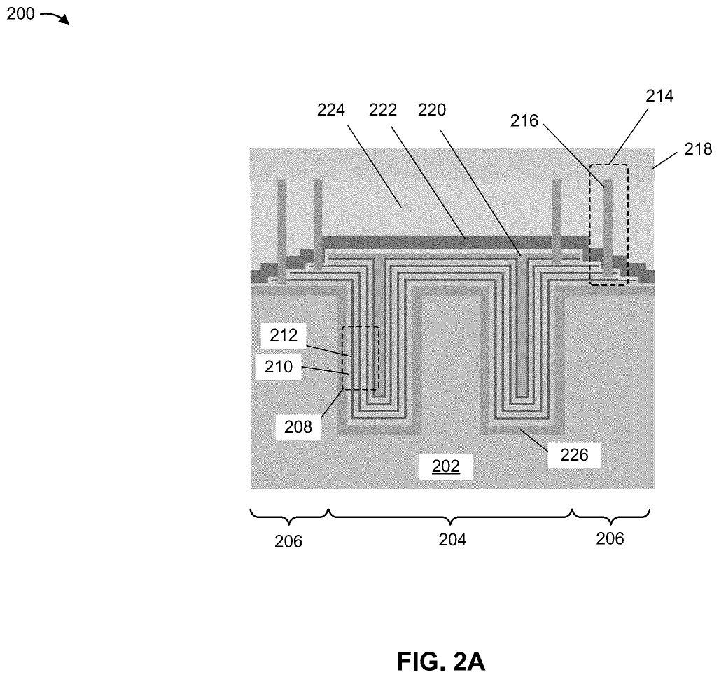

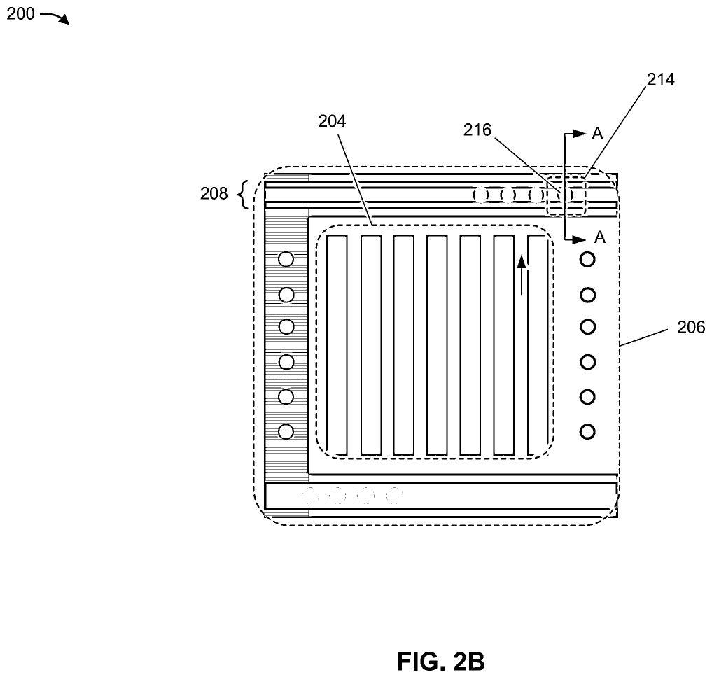

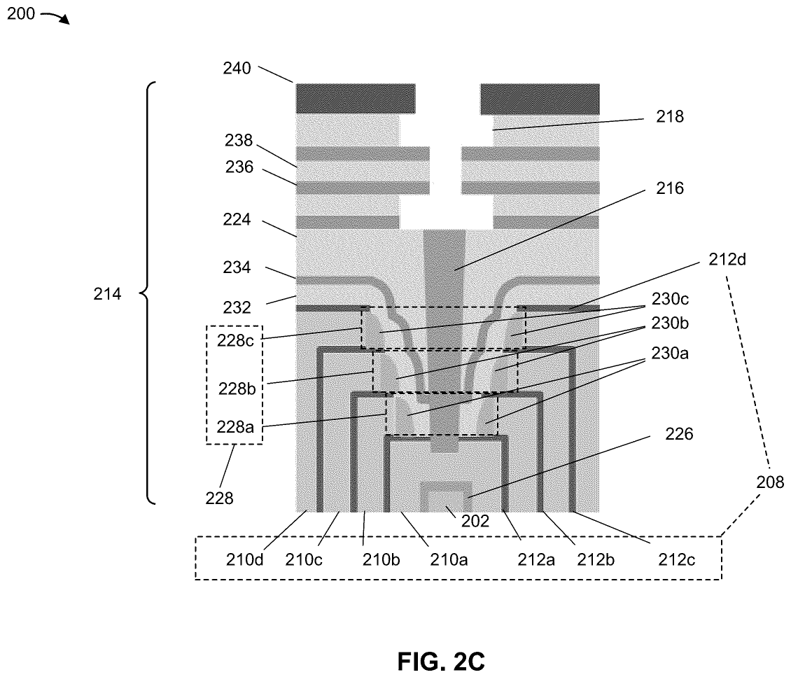

As described in connection with FIGS. 2A-5, and elsewhere herein, the one or more semiconductor processing tools 112-116 may perform a series of manufacturing operations. The series of manufacturing operations includes forming, from a side-view perspective, a stair-shaped cavity region that extends vertically into a layer stack including electrode layers interspersed with dielectric layers. The series of manufacturing operations includes forming, in ends of the electrode layers that are exposed through the stair-shaped cavity region, recesses that extend laterally into the electrode layers. The series of manufacturing operations includes forming, along contours of the stair-shaped cavity region and within the recesses, a layer of a dielectric material. The series of manufacturing operations includes removing portions of the dielectric layer to form spacer structures adjacent to the ends of the electrode layers.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of environment 100 may perform one or more functions described as being performed by another set of devices of environment 100.

FIGS. 2A-2C are diagrams of an example semiconductor structure 200 described herein. One or more of the semiconductor processing tools 102-116 may form the semiconductor structure 200 (e.g., a semiconductor device including the semiconductor structure 200).

As shown in the side view of FIG. 2A, the semiconductor structure 200 may include a semiconductor substrate 202 (e.g., a silicon wafer, among other examples), a capacitor region 204 (e.g., a deep trench capacitor region), and a circuit region 206 (e.g., landing circuitry) adjacent to the capacitor region 204. In some implementations, and as shown in FIG. 2A, the semiconductor may include multiples of the circuit region 206. The semiconductor structure 200 includes a layer stack 208 that includes one or more electrode layers 210 (e.g., conductive layers including a titanium nitride (TiN) material, among other examples) interspersed with one or more dielectric layers 212 (e.g., insulating layers including a dielectric material with dielectric constant more than 3, such as a silicon dioxide (SiO₂), silicon oxide (SiOₓ), aluminum dioxide (Al₂O₃), yttrium oxide (Y₂O₃), or zirconium dioxide (ZrO₂) material, among other examples). The layer stack 208 forms a capacitor over the capacitor region 204. The layer stack 208 of the one or more electrode layers 210 and the one or more dielectric layers 212 may conform to the shape of the recess in the semiconductor substrate 202 in which the layer stack 208 is formed.

The semiconductor structure 200 may further include a contact region 214 including a connection structure 216 (e.g., a conductive structure including a tungsten (W) material, among other examples). The connection structure 216 may make electrically connect an electrode layer (of the layer stack 208) and a conductive structure 218 (e.g., a conductive layer including a copper (Cu) material, among other examples) above the circuit region 206.

The semiconductor structure 200 may include additional dielectric layers and/or structures. For example, and as part of the semiconductor structure 200 (e.g., as part of forming a capacitor), the semiconductor structure 200 may include an aluminum dioxide (Al₂O₃) layer 220, a silicon nitride (SiN) layer 222, an inter-layer dielectric (ILD) layer 224, and/or an oxide layer 226, among other examples.

As shown in the top view of FIG. 2B (e.g., a plan view of an IC die or device including the semiconductor structure 200, among other examples), the capacitor region 204 may be in a central portion of the semiconductor structure 200. Additionally, or alternatively, the circuit region 206 may be around a peripheral portion of the semiconductor structure 200. In some implementations, the capacitor region 204 may consume approximately 47% to approximately 57% of an available area of the semiconductor structure 200 (e.g., of the IC die or device). Additionally, or alternatively, the circuit region 206 may consume approximately 43% to approximately 53% of the available area. However, other values and ranges for consumption of the available area by the capacitor region 204 and/or the circuit region 206 are within the scope of the present disclosure.

In some implementations, and as shown in FIG. 2B, the contact region 214 may be in the peripheral portion of the semiconductor structure 200. Additionally, or alternatively and as described in connection with FIG. 2C and elsewhere herein, the connection structure 216 may pass through one or more trench-shaped regions within the layer stack 208. In some implementations, the one or more trench-shaped regions within the layer stack 208 are part of a stair-shaped profile within the layer stack 208.

FIG. 2C shows an example section view A-A (e.g., the section A-A in FIG. 2B) of the semiconductor structure 200. The section view A-A includes the contact region 214 and the connection structure 216.

As shown in FIG. 2C, the layer stack 208 includes electrode layers 210a-210d (e.g., conductive layers including a TiN material, among other examples) interspersed with dielectric layers 212a-212d (e.g., insulating layers including a high-k dielectric material such as a silicon dioxide (SiO₂) material, among other examples). In some implementations, edge regions over the electrode layers 210b-210d may include portions of the dielectric layers 212b-212c.

FIG. 2C further shows trench regions 228 that include spacer structures 230. Each of the spacer structures 230 may include a dielectric material such as a silicon nitride (SiN) material, a silicon dioxide (SiO₂) material, a silicon carbide (SiC) material, or an aluminum dioxide (Al₂O₃) material, among other examples.

As shown in FIG. 2C, the trench region 228a includes spacer structures 230a adjacent to approximately vertical end surfaces of the electrode layer 210b (e.g., opposing spacer structures on opposing, approximately vertical end surfaces of the electrode layer 210b).

Above the trench region 228a, the trench region 228b includes spacer structures 230b adjacent to approximately vertical end surfaces of the electrode layer 210c (e.g., opposing spacer structures on opposing, approximately vertical end surfaces of the electrode layer 210c). In some implementations, a distance between the vertical end surfaces of the electrode layer 210c may be greater than a distance between the vertical end surfaces of the electrode layer 210b (e.g., the trench region 228b may have a greater width relative to the trench region 228a).

Above the trench region 228b, the trench region 228c includes spacer structures 230c adjacent to approximately vertical end surfaces of the electrode layer 210d (e.g., opposing spacer structures on opposing, approximately vertical end surfaces of the electrode layer 210d). In some implementations, a distance between the vertical end surfaces of the electrode layer 210d may be greater than a distance between the vertical end surfaces of the electrode layer 210c (e.g., the trench region 228c may have a greater width relative to the trench region 228b).

The spacer structures 230a-230c are included to reduce the likelihood of electrical shorting or leakage between the connection structure 216 and the electrode layers 210a-210d that might otherwise result from process variation in landing the connection structure 216 on the electrode layer 210a. In some implementations, use of the spacer structures 230a-230c in the semiconductor structure 200 may provide for a greater critical dimension overlay window (e.g., provide for greater additional photolithography and/or etching margins).

For example, if lateral variation in a landing location of the connection structure 216 on the electrode layer 210a results in the connection structure 216 being positioned closer to one side of the trench region 228a, the spacer structures 230a may provide a layer of non-conductive material between the connection structure 216 and the one side of the trench region 228a (corresponding to one end of the electrode layer 210b in the trench region 228a). The layer of non-conductive material between the connection structure 216 and the one side of the trench region 228a prevents the connection structure 216 from physically contacting the one end of the electrode layer 210b in the trench region 228a, which prevents electrical shorting from occurring between the connection structure 216 and the one end of the electrode layer 210b in the trench region 228a. Moreover, the layer of non-conductive material between the connection structure 216 and the one side of the trench region 228a acts as an electrical barrier between the connection structure 216 and the one side of the trench region 228a, which reduces current leakage between the connection structure 216 and the one side of the trench region 228a.

The other spacers structures (e.g., 230b, 230c, and other spacer structures 230) reduce the likelihood of electrical shorting or leakage for other electrode layers in the semiconductor structure 200 in a similar manner.

The semiconductor structure 200 further includes a dielectric layer 232. The dielectric layer 232 may include an undoped silicon glass (USG) material or another like material. The dielectric layer 232 may be between the connection structure 216 and one or more of the spacer structures 230a-230c. In some implementations, a thickness of the dielectric layer 232 may be included in a range of approximately 180 angstroms (Å) to approximately 228 Å. However, other values and ranges for the dielectric layer 232 are within the scope of the present disclosure.

The semiconductor structure 200 further includes a dielectric layer 234. The dielectric layer 234 may be on the dielectric layer 232 and include a silicon nitride (SiN) material, among other examples. In some implementations, a thickness of the dielectric layer 234 may be included in a range of approximately 675 angstroms Å to approximately 825 Å. However, other values and ranges for the dielectric layer 234 are within the scope of the present disclosure.

The semiconductor structure 200 further includes the inter-dielectric (ILD) layer 224. The ILD layer 224 may be on the dielectric layer 234 and include a silicon dioxide (SiO₂) material, among other examples. In some implementations, a thickness of the ILD layer 224 may be included in a range of approximately 4150 angstroms (Å) to approximately 4950 Å. However, other values and ranges for the ILD layer 224 are within the scope of the present disclosure.

As shown in FIG. 2C, the semiconductor structure 200 may include additional layers such as one or more dielectric layers 236 that include a polyethylene silicon nitride (PESiN) material, one or more dielectric layers 238 (e.g., including a silicon oxide material), and/or a passivation layer 240 that includes an aluminum dioxide (Al₂O₃) material, among other examples. In some implementations, and as shown in FIG. 2C, the conductive structure 218 is adjacent to one or more of the dielectric layers 236 and 238, below the passivation layer 240, and provide an electrical connection to the connection structure 216.

As indicated above, FIGS. 2A-2C are provided as examples. Other examples may differ from what is described with regard to FIGS. 2A-2C.

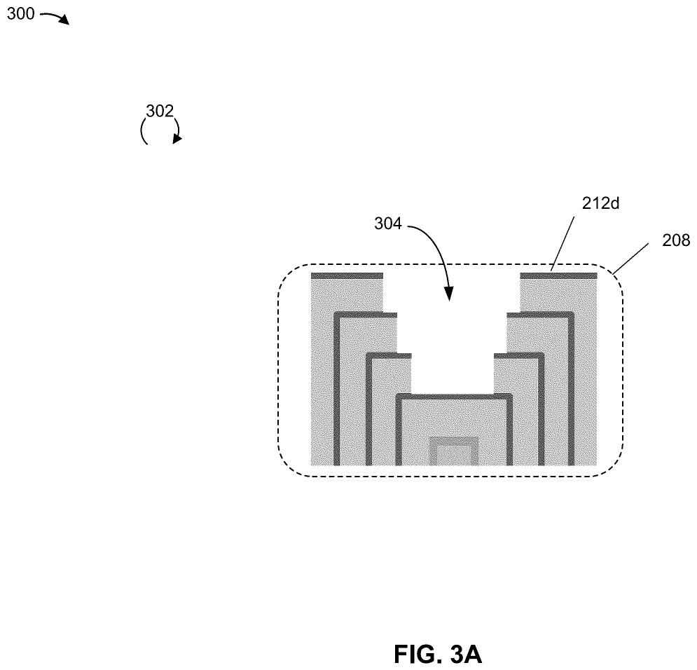

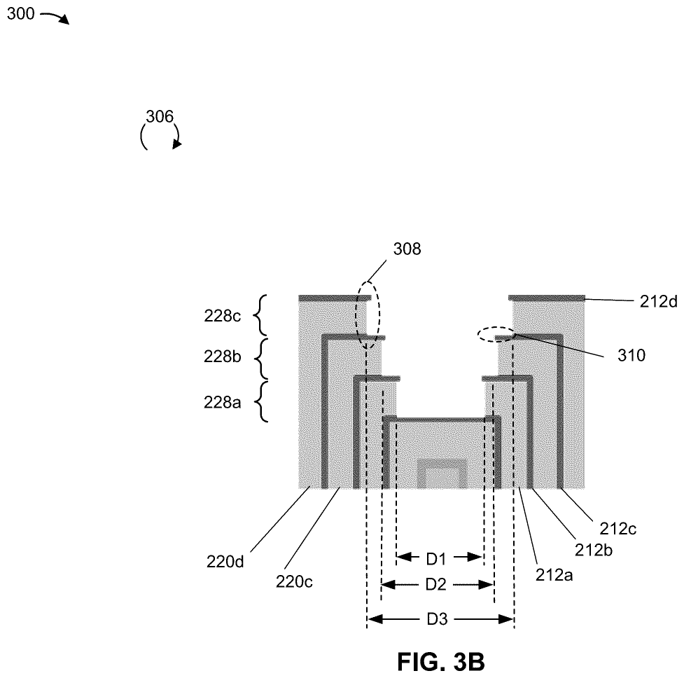

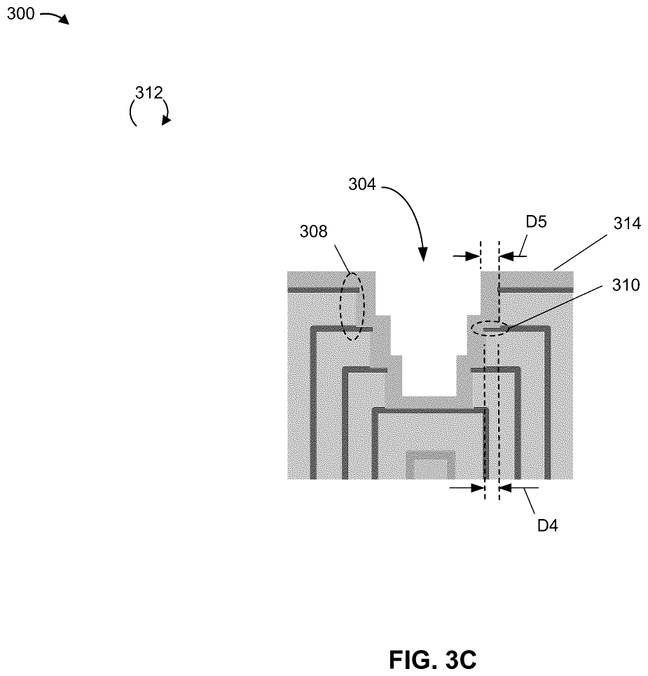

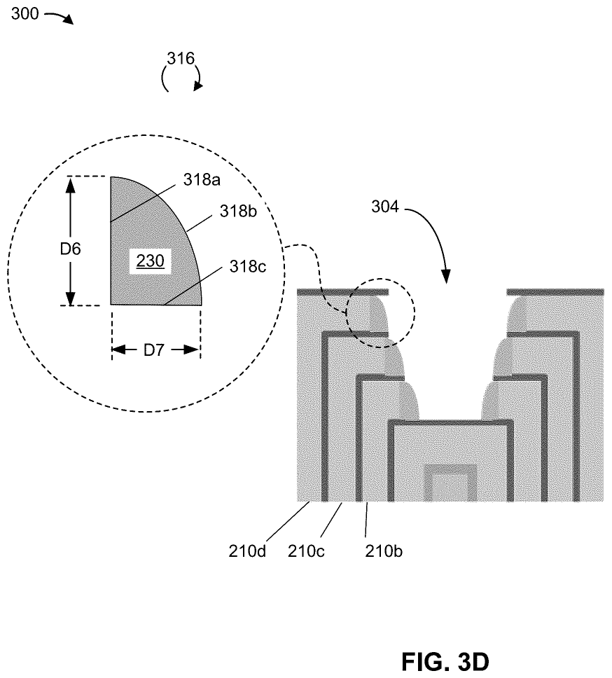

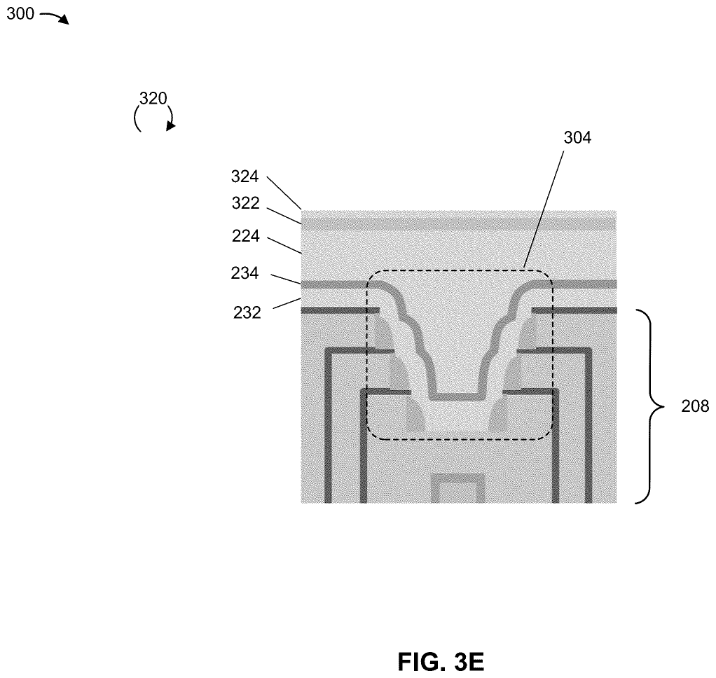

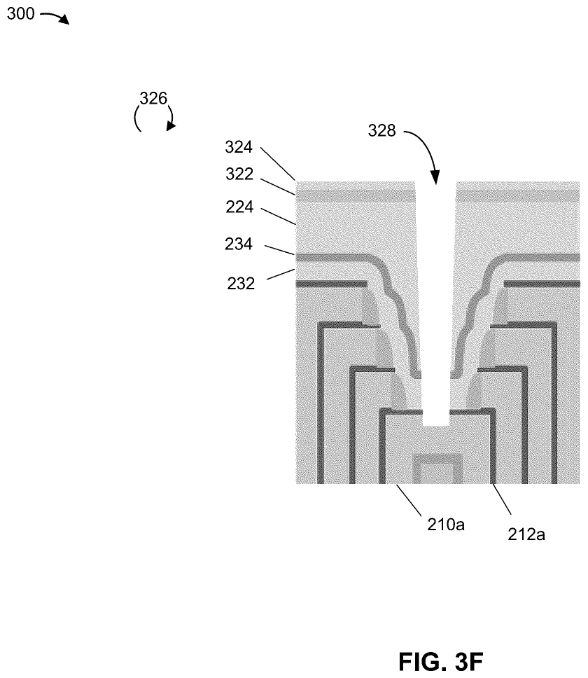

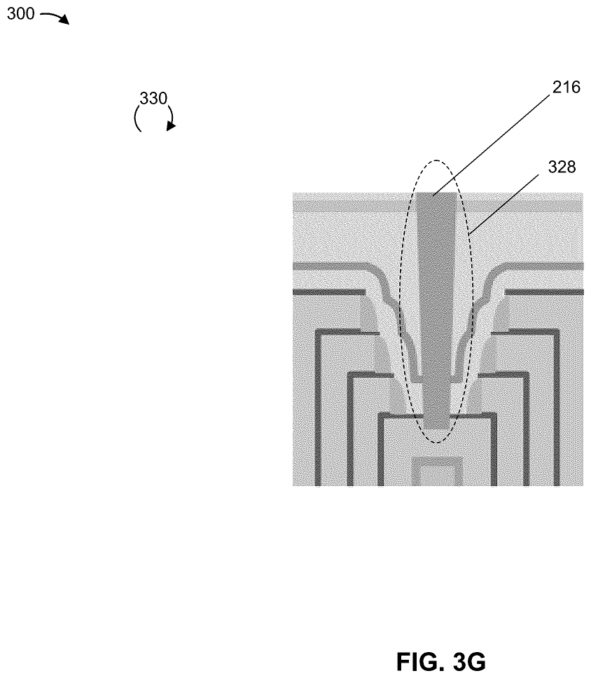

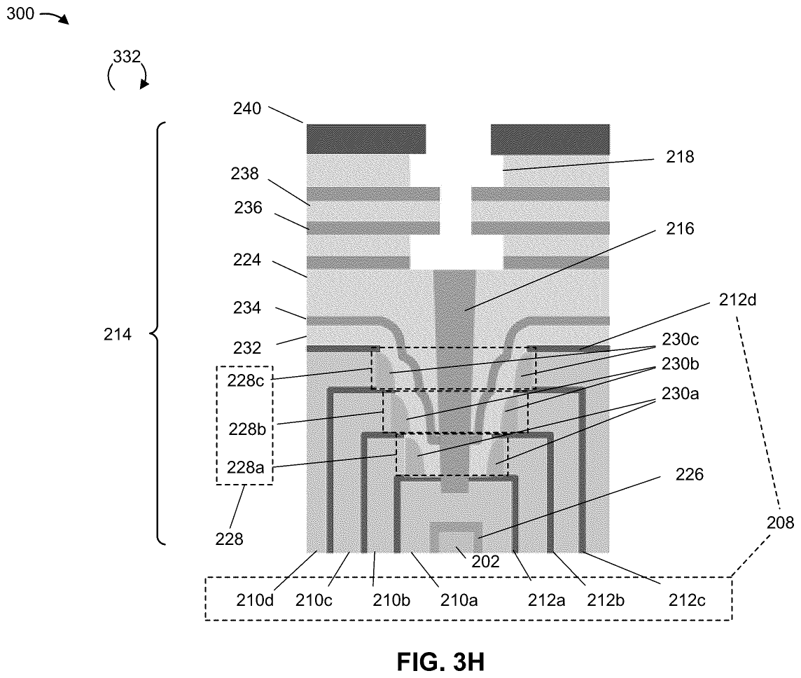

FIGS. 3A-3H are diagrams of an example manufacturing process 300 used to fabricate the semiconductor structure 200 described herein. The example manufacturing process 300 may use one or more of the semiconductor manufacturing tools 102-116 as described in connection with FIG. 1.

In some implementations, and as part of a series of operations 302 shown in FIG. 3A, a sequence of photoresist patterns may be used to etch the layer stack 208 to form a stair-shaped cavity region 304. In these implementations, for each photoresist pattern, the deposition tool 102 forms a photoresist layer on the dielectric layer 212d. The exposure tool 104 exposes the photoresist layer to a radiation source to pattern the photoresist layer. The develop tool 106 develops and removes portions of the photoresist layer to expose a pattern. The etch tool 108 etches the layer stack 208 based on the pattern to form a portion of the stair-shaped cavity region 304 in the layer stack 208. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching a portion of the stair-shaped cavity region 304 based on a pattern. In some implementations, a photoresist removal tool removes the remaining portions of the photoresist layer (e.g., using a chemical stripper, plasma ashing, and/or another technique).

In some implementations, as part of a series of operations 306 shown in FIG. 3B, recesses 308 are formed in exposed ends of each of the electrode layers 214b-214d. As part of forming the recesses 308, and as shown in FIG. 3B, edge regions 310 (e.g., a stair-shaped profile including stairs) may be formed in dielectric layers 212b-212d. In some implementations, portions of the edge regions 310 “overhang” the recesses 308. To form the recesses 308, the etch tool 108 may perform a wet-etching operation selectively remove portions of the electrode layers 214b-214d. For example, in a case where the electrode layers 214b-214d include a TiN material, the wet-etching operation may correspond to “hot wet dip” technique in which a hydrogen peroxide fluid is used to laterally etch the electrode layers 214b-214d to form the recesses 308. Such a wet-etching operation may occur at approximately 70 degrees Celsius and, for every 10 seconds of duration, remove approximately 5 nanometers of the TiN material. However, other fluids, temperatures, and durations are within the scope of the present disclosure.

After the series of operations 306, the trench region 228a includes a width D1. For example, the width D1 may be included in a range of approximately 0.32 microns to approximately 0.38 microns. Additionally, or alternatively, the trench region 228b (above the trench region 228a) includes a width D2 that is greater relative to D1. For example, the width D2 may be included in a range of approximately 0.36 microns to approximately 0.44 microns. Additionally, or alternatively, the trench region 228c (above the trench region 228b) includes a width D3 that is greater relative to D2. For example, the width D3 may be included in a range of approximately 0.41 microns to approximately 0.49 microns. However, other values and ranges for the widths D1, D2, and D3 are within the scope of the present disclosure.

As shown in FIG. 3C, as part of a series of operations 312, a dielectric layer 314 is formed along contours of the stair-shaped cavity region 304 and within the recesses 308. The deposition tool 102 may deposit the dielectric layer 314 in a PVD operation, an ALD operation, a CVD operation, an epitaxy operation, an oxidation operation, another type of deposition operation described in connection with FIG. 1, and/or another suitable deposition operation. The dielectric layer 314 may include a silicon nitride (SiN) material, a silicon dioxide (SiO₂) material, or a silicon carbide (SiC) material, among other examples.

In FIG. 3C, the edge region 310 includes a width D4 and the dielectric layer 314 includes a width D5. In some implementations, the width D5 is greater than or equal to the width D4. In such implementations, the dielectric layer 314 may perform as an etch stop. If the width D5 is less than D4, however, the edge region 310 may be exposed to increase a risk of etching damage (e.g., an “etch through” of the edge region 310).

As shown in FIG. 3D, as part of a series of operations 316, the spacer structures 230 are formed. As part of the series of operations 316, the etch tool 108 may perform a plasma etch operation, a wet chemical etch operation, and/or another type of etch operation. Each of the spacer structures 230 may include a an approximately vertical surface 318a that faces an approximately vertical end of an adjacent electrode layer. Additionally, or alternatively, each of the spacer structures 230 may include an approximately convex surface 318b that is opposite the approximately vertical surface 318a. In other words, the spacer structures 230 may have a rounded outward-facing surface (e.g., the convex surface 318b) facing the stair-shaped cavity region 304 as a result of etching the dielectric layer 314. Additionally, or alternatively, each of the spacer structures 230 may include an approximately lateral surface 318c below the approximately vertical surface 318a and below the approximately convex surface 318b. In some implementations, and as shown, the spacer structures 230 may be staggered, horizontally, within the stair-shaped cavity region 304 based on relative depths within the stair-shaped cavity region 304.

The spacer structure(s) 230 may include a height D6 and width D7. The height D6 may vary with a thickness of an electrode layer (e.g., a thickness of one or more of the electrode layers 210b-210d). In particular, the height D6 of a spacer structure 230 may be approximately equal to or greater than a thickness of a corresponding electrode layer on which the spacer structure 230 so that the ends of the electrode layer are fully covered by the spacer structure 230. This ensures that there are no gaps between the spacer structure 230 and the dielectric layers on opposing sides of the electrode layer, which reduces the likelihood of current leakage and/or shorting. Additionally, or alternatively, the width D7 may be included in a range of approximately 1 nanometer to approximately 50 nanometers. If the width D7 is less than approximately 1 nanometer, the spacer structure(s) 230 may not sufficiently insulate and adjacent electrode layer to prevent shorting. If the width D7 is greater than approximately 50 nanometers, the spacer structure(s) 230 may interfere with a connection structure (e.g., the connection structure 216). However, other values and ranges for the width D7 are within the scope of the present disclosure.

In some implementations, the spacer structure(s) 230 may protect one or more adjacent electrode layers (e.g., the electrode layers 210b-210c) from oxidation. In addition to benefits of the spacer structure(s) 230 described above (e.g., reducing a likelihood of electrical shorting in the semiconductor structure 200 and/or a reduction in a size of an IC device including the semiconductor structure 200, among other examples), the oxidation protection provided by the spacer structures(s) 230 may allow an increase in queue times to improve logistics within the manufacturing environment 100 described in connection with FIG. 1.

As shown in FIG. 3E, one or more layers of material are formed over the layer stack 208 and/or within the stair-shaped cavity region 304. In some implementations, one or more of the layers of material may fill the stair-shaped cavity region 304. As part of a series of operations 320, the deposition tool 102 may deposit the dielectric layer 232, the dielectric layer 234, and the ILD layer 224 in a PVD operation, an ALD operation, a CVD operation, an epitaxy operation, an oxidation operation, another type of deposition operation described in connection with FIG. 1, and/or another suitable deposition operation.

Additionally, or alternatively and as part of the series of operations 320, the deposition tool 102 may deposit a dielectric layer 322 and a dielectric layer 324 in a PVD operation, an ALD operation, a CVD operation, an epitaxy operation, an oxidation operation, another type of deposition operation described in connection with FIG. 1, and/or another suitable deposition operation. Additionally, or alternatively and as part of the series of operations 320, the planarization tool 110 planarizes the dielectric layer 324 after the deposition tool 102 deposits the dielectric layer 324.

In some implementations, the dielectric layer 322 includes a silicon oxynitride (SiON) material having a thickness that is included in a range of approximately 450 Å to approximately 228 Å. In some implementations, the dielectric layer 324 includes an undoped silicon glass (USG) material having a thickness that is included in a range of approximately 180 Å to approximately 228 Å. However, other materials, and values or ranges of thicknesses, for the dielectric layer 322 and the dielectric layer 324 are within the scope of the present disclosure.

As shown in FIG. 3F, a series of operations 326 may be performed to form a cavity region 328 that exposes an electrode layer (e.g., the electrode layer 210a, among other examples). In some implementations, the cavity region 328 includes a tapered shape.

The series of operations 326 may form the cavity region 328 through the dielectric layer 324, through the dielectric layer 322, through the dielectric layer 236, through the dielectric layer 234, and through the dielectric layer 212a to expose the electrode layer 210a. In some implementations, a pattern in a photoresist layer is used to etch the dielectric layers 324, 322, 236, 234, and 232 to form the cavity region 328. In these implementations, the deposition tool 102 forms the photoresist layer on the dielectric layer 324. The exposure tool 104 exposes the photoresist layer to a radiation source to pattern the photoresist layer. The develop tool 106 develops and removes portions of the photoresist layer to expose the pattern. The etch tool 108 etches the dielectric layers 324, 322, 236, 234, and 232 based on the pattern to form the cavity region 328 in the dielectric layers 324, 322, 236, 234, and 232. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the dielectric layers 324, 322, 236, 234, and 232 based on a pattern. In some implementations, a photoresist removal tool removes the remaining portions of the photoresist layer (e.g., using a chemical stripper, plasma ashing, and/or another technique).

As shown in FIG. 3G, a series of operations 330 may be performed to form the connection structure 216 in the cavity region 328. For example, to form the connection structure 216, the deposition tool 102 and/or the plating tool 112 may deposit a layer of a tungsten (W) material in the cavity region 328 and on the dielectric layer 324 in a CVD operation, a PVD operation, an ALD operation, an electroplating operation, another deposition operation described above in connection with FIG. 1, and/or another suitable deposition operation. In some implementations, a seed layer is first deposited, and the layer of tungsten material is deposited on the seed layer. As shown in FIG. 3G, the connection structure 216 connects with the electrode layer 210a. In some implementations, the planarization tool 110 planarizes the layer of tungsten material after the deposition tool 102 and/or the plating tool 112 deposits the layer of tungsten material to form the connection structure 216.

As shown in FIG. 3H, a series of operations 332 may be performed to form additional layers and/or features of the contact region 214. For example, the series of operations may include the deposition tool 102 depositing materials corresponding to the conductive structure 218, the one or more dielectric layers 236 and 238, and/or the passivation layer 240 in a PVD operation, an ALD operation, an electroplating operation, another deposition operation described above in connection with FIG. 1, and/or another suitable deposition operation.

Additionally, or alternatively as part of the series of operations 332, the etch tool 108 may etch the one or more dielectric layers 236 and 238 as part of forming features of the conductive structure 218. For example, a sequence of photoresist patterns may be used to etch the layer the one or more dielectric layers 236 and 238 to form shapes and/or cavities for the conductive structure 218. In these implementations, and for each photoresist pattern, the deposition tool 102 forms a photoresist layer. The exposure tool 104 exposes the photoresist layer to a radiation source to pattern the photoresist layer. The develop tool 106 develops and removes portions of the photoresist layer to expose the pattern. The etch tool 108 removes material from the one or more dielectric layers 236 and 238 based on the patterns to form the shapes and/or cavities for the conductive structure 218. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the one or more dielectric layers based on a pattern. In some implementations, a photoresist removal tool removes the remaining portions of the photoresist layer (e.g., using a chemical stripper, plasma ashing, and/or another technique).

Different implementations of a device (e.g., an IC device) including the semiconductor structure 200 are possible. For example, and as shown FIGS. 3A-3H in connection with FIGS. 2A-2C, an implementation of a device (e.g., the semiconductor structure 200) includes a capacitor region 204. The device includes a circuit region 206 adjacent to the capacitor region 204. The circuit region 206 includes a first approximately vertical end of a first conductive layer (e.g., the electrode layer 210c) adjacent to a first trench region (e.g., the trench region 228b), where the first trench region includes a first width (e.g., the width D2). The circuit region 206 includes a second approximately vertical end of a second conductive layer (e.g., the electrode layer 210d) adjacent to a second trench region (e.g., the trench region 228c), where the second trench region is above the first trench region, and where the second trench region includes a second width (e.g., the width D3) that is greater relative to the first width. The circuit region 206 includes an approximately lateral edge region (e.g., the edge region 310) of a dielectric layer (e.g., the dielectric layer 212c, among other examples), where the approximately lateral edge region is between the first approximately vertical end of the first conductive layer and the second approximately vertical end of the second conductive layer. The circuit region 206 includes a spacer structure (e.g., the spacer structure 230b, among other examples) on the approximately lateral edge region, where the spacer structure is over the first conductive layer, and where the spacer structure is adjacent to the second approximately vertical end of the second conductive layer.

Additionally, alternatively, an implementation of the device includes a first electrode layer (e.g., the electrode layer 210a) of a capacitor region 204. The device includes a second electrode layer (e.g., the electrode layer 210b) of the capacitor region 204. The second electrode layer includes first opposing end surfaces over the first electrode layer, where the first opposing end surfaces are separated by a first distance (e.g., the distance D1), and where the first opposing end surfaces face one another. The device includes first opposing spacer structures (e.g., the spacer structures 230a) adjacent to the first opposing end surfaces. The device includes a third electrode layer (e.g., the electrode layer 210c) of the capacitor region 204 including second opposing end surfaces over the second electrode layer, where the second opposing end surfaces are separated by a second distance (e.g., the distance D2) that is greater relative to the first distance, and where the second opposing end surfaces face one another. The device includes second opposing spacer structures (230b) adjacent to the second opposing end surfaces.

As indicated above, FIGS. 3A-3H are provided as examples. Other manufacturing processes may differ from what is described with regard to FIGS. 3A-3H.

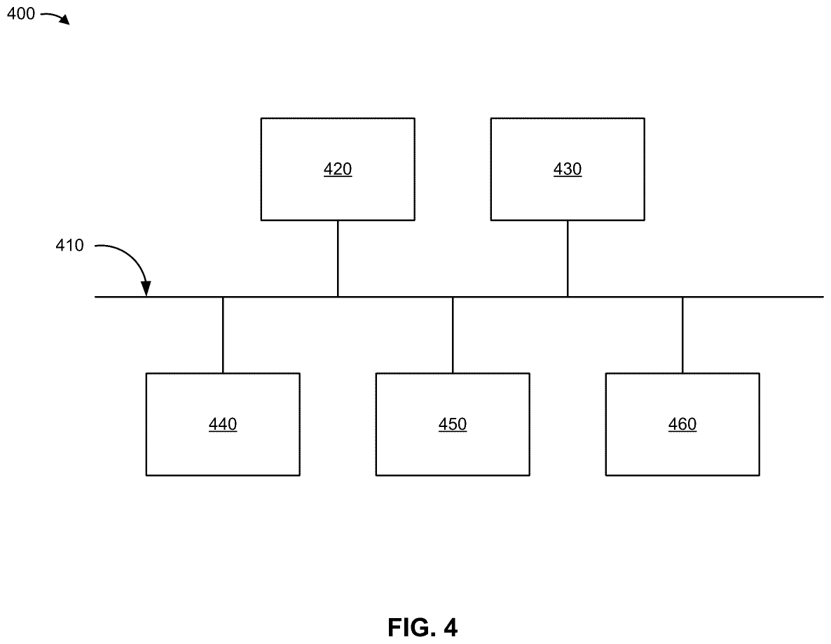

FIG. 4 is a diagram of example components of a device 400 associated with semiconductor device and methods of manufacturing. Device 400 may correspond to one or more of the semiconductor processing tools 102-116. In some implementations, one or more of the semiconductor processing tools 102-116 may include one or more devices 400 and/or one or more components of device 400. As shown in FIG. 4, device 400 may include a bus 410, a processor 420, a memory 430, an input component 440, an output component 450, and a communication component 460.

Bus 410 may include one or more components that enable wired and/or wireless communication among the components of device 400. Bus 410 may couple together two or more components of FIG. 4, such as via operative coupling, communicative coupling, electronic coupling, and/or electric coupling. Processor 420 may include a central processing unit, a graphics processing unit, a microprocessor, a controller, a microcontroller, a digital signal processor, a field-programmable gate array, an application-specific integrated circuit, and/or another type of processing component. Processor 420 is implemented in hardware, firmware, or a combination of hardware and software. In some implementations, processor 420 may include one or more processors capable of being programmed to perform one or more operations or processes described elsewhere herein.

Memory 430 may include volatile and/or nonvolatile memory. For example, memory 430 may include random access memory (RAM), read only memory (ROM), a hard disk drive, and/or another type of memory (e.g., a flash memory, a magnetic memory, and/or an optical memory). Memory 430 may include internal memory (e.g., RAM, ROM, or a hard disk drive) and/or removable memory (e.g., removable via a universal serial bus connection). Memory 430 may be a non-transitory computer-readable medium. Memory 430 stores information, instructions, and/or software (e.g., one or more software applications) related to the operation of device 400. In some implementations, memory 430 may include one or more memories that are coupled to one or more processors (e.g., processor 420), such as via bus 410.

Input component 440 enables device 400 to receive input, such as user input and/or sensed input. For example, input component 440 may include a touch screen, a keyboard, a keypad, a mouse, a button, a microphone, a switch, a sensor, a global positioning system sensor, an accelerometer, a gyroscope, and/or an actuator. Output component 450 enables device 400 to provide output, such as via a display, a speaker, and/or a light-emitting diode. Communication component 460 enables device 400 to communicate with other devices via a wired connection and/or a wireless connection. For example, communication component 460 may include a receiver, a transmitter, a transceiver, a modem, a network interface card, and/or an antenna.

Device 400 may perform one or more operations or processes described herein. For example, a non-transitory computer-readable medium (e.g., memory 430) may store a set of instructions (e.g., one or more instructions or code) for execution by processor 420. Processor 420 may execute the set of instructions to perform one or more operations or processes described herein. In some implementations, execution of the set of instructions, by one or more processors 420, causes the one or more processors 420 and/or the device 400 to perform one or more operations or processes described herein. In some implementations, hardwired circuitry is used instead of or in combination with the instructions to perform one or more operations or processes described herein. Additionally, or alternatively, processor 420 may be configured to perform one or more operations or processes described herein. Thus, implementations described herein are not limited to any specific combination of hardware circuitry and software.

The number and arrangement of components shown in FIG. 4 are provided as an example. Device 400 may include additional components, fewer components, different components, or differently arranged components than those shown in FIG. 4. Additionally, or alternatively, a set of components (e.g., one or more components) of device 400 may perform one or more functions described as being performed by another set of components of device 400.

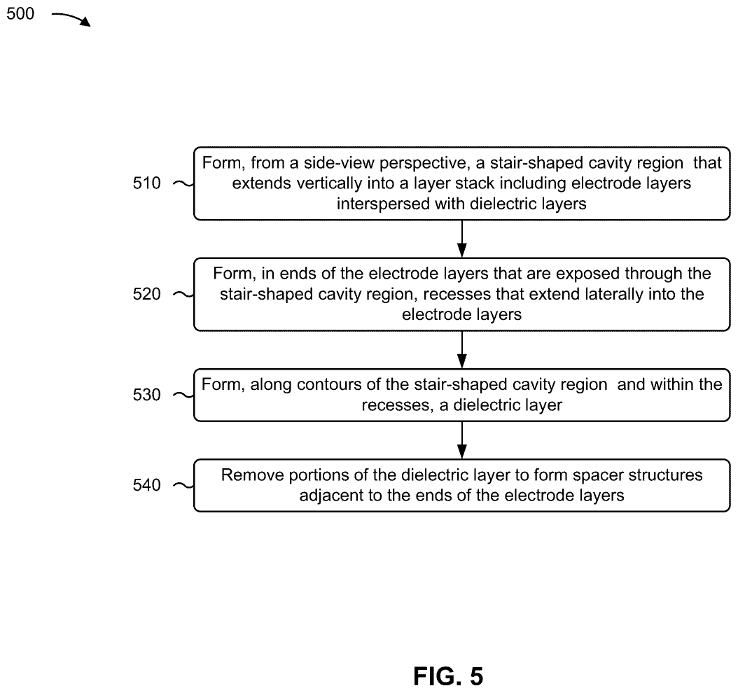

FIG. 5 is a flowchart of an example process 500 associated with self-aligned contact landing on a metal circuit. In some implementations, one or more process blocks of FIG. 5 are performed by a one or more of the semiconductor processing tools 102-116. Additionally, or alternatively, one or more process blocks of FIG. 5 may be performed by one or more components of device 400, such as processor 420, memory 430, input component 440, output component 450, and/or communication component 460.

As shown in FIG. 5, process 500 may include forming, from a side-view perspective, a stair-shaped cavity region that extends vertically into a layer stack including electrode layers interspersed with dielectric layers (block 510). For example, one or more of the semiconductor processing tools 102-116, such as the etch tool 108 among other examples, may form, from a side-view perspective, a stair-shaped cavity region 304 that extends vertically into a layer stack 208 including electrode layers (e.g., the electrode layers 210a-210d) interspersed with dielectric layers (e.g., the dielectric layers 212a-212c), as described above.

As further shown in FIG. 5, process 500 may include forming, in ends of the electrode layers that are exposed through the stair-shaped cavity region, recesses that extend laterally into the electrode layers (block 520). For example, one or more of the semiconductor processing tools 102-116, such as the etch tool 108 among other examples, may form, in ends of the electrode layers that are exposed through the stair-shaped cavity region 304, recesses 308 that extend laterally into the electrode layers, as described above.

As further shown in FIG. 5, process 500 may include forming, along contours of the stair-shaped cavity region and within the recesses, a layer of a dielectric material (block 530). For example, one or more of the semiconductor processing tools 102-116, such as the deposition tool 102 among other examples, may form, along contours of the stair-shaped cavity region 304 and within the recesses 308, a dielectric layer 314, as described above.

As further shown in FIG. 5, process 500 may include removing portions of the dielectric layer to form spacer structures adjacent to the ends of the electrode layers (block 540). For example, one or more of the semiconductor processing tools 102-116, such as the etch tool 108 among other examples, may remove portions of the dielectric layer 314 to form spacer structures 230 adjacent to the ends of the electrode layers, as described above.

Process 500 may include additional implementations, such as any single implementation or any combination of implementations described below and/or in connection with one or more other processes described elsewhere herein.

In a first implementation, forming the recesses 308 that extend laterally into the electrode layers (e.g., the electrode layers 210a-210d) includes performing an etching operation to laterally etch a material of the electrode layers to form the recesses 308.

In a second implementation, alone or in combination with the first implementation, performing the etching operation includes performing a wet-etching operation in which a hydrogen peroxide fluid is used to selectively etch the material of the electrode layers (e.g., the electrode layers 210a-210d), where the material of the electrode layers includes a titanium nitride material.

In a third implementation, alone or in combination with one or more of the first and second implementations, forming the recesses 308 that extend laterally into the electrode layers (e.g., the electrode layers 210a-210d) includes forming edge regions 310 of dielectric layers (e.g., the dielectric layers 212a-212c) adjacent to the recesses, where the edge regions 310 include a width D4.

In a fourth implementation, alone or in combination with one or more of the first through third implementations, the width D4 corresponds to a first width and forming the dielectric layer 314 includes forming the dielectric layer 314 to include a second width D5 that, relative to the first width, is greater than or equal to the first width.

In a fifth implementation, alone or in combination with one or more of the first through fourth implementations, removing the portions of the dielectric layer 314 to form the spacer structures 230 adjacent to the ends of the electrode layers (e.g., the electrode layers 210a-210d) includes removing the portions of the dielectric layer 314 to stagger, horizontally, the spacer structures 230 within the stair-shaped cavity region 304, where the stagger is based on respective depths of the spacer structures 230 within the stair-shaped cavity region 304.

In a sixth implementation, alone or in combination with one or more of the first through fifth implementations, process 500 includes forming one or more dielectric layers (e.g., the dielectric layers 224, 232, and 236) that fill the stair-shaped cavity region 304, and forming a connection structure 216 through the one or more dielectric layers and between the spacer structures 230, where forming the connection structure 216 through the one or more dielectric layers and between the spacer structures 230 reduces a likelihood of electrical shorting between one or more of the electrode layers (e.g., one or more of the electrode layers 210a-210d) through the connection structure 216.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

Some implementations described herein include an IC device including landing circuitry and methods of formation. The landing circuitry, which may be part of a trench capacitor region, includes a stair-shaped profile on a silicon substrate of the IC device. The landing circuitry includes electrode layers of the trench capacitor region interspersed with layers of a dielectric material. The landing circuitry further includes spacer structures on ends of the electrode layers along the stair-shaped profile.

Including the spacer structures in the landing circuitry of the IC device may reduce a risk of shorting and/or leakage within IC device, which may increase performance of the IC device and/or increase a yield of the IC device. In this way, a risk of shorting and/or leakage, a quality and/or a reliability of the IC device during a field use of the IC device may be improved. Furthermore, and through an increase in a density of the capacitor region, a size of the IC device may be reduced, leading to a reduction in resources (e.g., manufacturing tools, computing resources, and materials) to fabricate a volume of the IC device.

As described in greater detail above, some implementations described herein provide a device. The device includes a capacitor region. The device includes a circuit region adjacent to the capacitor region. The circuit region includes a first approximately vertical end of a first conductive layer adjacent to a first trench region, where the first trench region includes a first width. The circuit region includes a second approximately vertical end of a second conductive layer adjacent to a second trench region, where the second trench region is above the first trench region, and where the second trench region includes a second width that is greater relative to the first width. The circuit region includes an approximately lateral edge region of a dielectric layer, where the approximately lateral edge region is between the first approximately vertical end of the first conductive layer and the second approximately vertical end of the second conductive layer. The circuit region includes a spacer structure on the approximately lateral edge region, where the spacer structure is over the first conductive layer, and where the spacer structure is adjacent to the second approximately vertical end of the second conductive layer.

As described in greater detail above, some implementations described herein provide a device. The device includes a first electrode layer of a capacitor region. The device includes a second electrode layer of the capacitor region. The second electrode layer includes first opposing end surfaces over the first electrode layer, where the first opposing end surfaces are separated by a first distance, and where the first opposing end surfaces face one another. The device includes first opposing spacer structures adjacent to the first opposing end surfaces. The device includes a third electrode layer of the capacitor region including second opposing end surfaces over the second electrode layer, where the second opposing end surfaces are separated by a second distance that is greater relative to the first distance, and where the second opposing end surfaces face one another. The device includes second opposing spacer structures adjacent to the second opposing end surfaces.

As described in greater detail above, some implementations described herein provide a method. The method includes forming, from a side-view perspective, a stair-shaped cavity region that extends vertically into a layer stack including electrode layers interspersed with dielectric layers. The method includes forming, in ends of the electrode layers that are exposed through the stair-shaped cavity region, recesses that extend laterally into the electrode layers. The method includes forming, along contours of the stair-shaped cavity region and within the recesses, a layer of a dielectric material. The method includes removing portions of the dielectric layer to form spacer structures adjacent to the ends of the electrode layers.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a capacitor region; and
a circuit region adjacent to the capacitor region comprising:
a first approximately vertical end of a first conductive layer adjacent to a first trench region,
wherein the first trench region includes a first width;
a second approximately vertical end of a second conductive layer adjacent to a second trench region,
wherein the second trench region is above the first trench region, and
wherein the second trench region includes a second width that is greater relative to the first width;
an approximately lateral edge region of a dielectric layer,
wherein the approximately lateral edge region is between the first approximately vertical end of the first conductive layer and the second approximately vertical end of the second conductive layer; and
a spacer structure on the approximately lateral edge region,
wherein the spacer structure is over the first conductive layer, and
wherein the spacer structure is adjacent to the second approximately vertical end of the second conductive layer.

2. The device of claim 1, wherein a width of the spacer structure is in a range of approximately 1 nanometer to approximately 50 nanometers.

3. The device of claim 1, wherein the approximately lateral edge region comprises a third width, and
wherein the spacer structure comprises:
a fourth width that is approximately equal to the third width.

4. The device of claim 1, wherein the spacer structure comprises:
an approximately vertical surface facing the second approximately vertical end of the second conductive layer,
an approximately convex surface opposite the approximately vertical surface and
an approximately lateral surface below the approximately vertical surface and the approximately convex surface.

5. The device of claim 4, further comprising:
a connection structure adjacent to the approximately convex surface.

6. The device of claim 5, wherein the connection structure connects to a third conductive layer below the first conductive layer.

7. A device, comprising:
a first electrode layer of a capacitor region;
a second electrode layer of the capacitor region comprising first opposing end surfaces over the first electrode layer,
wherein the first opposing end surfaces are separated by a first distance, and
wherein the first opposing end surfaces face one another;
first opposing spacer structures adjacent to the first opposing end surfaces;
a third electrode layer of the capacitor region comprising second opposing end surfaces over the second electrode layer,
wherein the second opposing end surfaces are separated by a second distance that is greater relative to the first distance, and
wherein the second opposing end surfaces face one another; and
second opposing spacer structures adjacent to the second opposing end surfaces.

8. The device of claim 7, wherein the first opposing spacer structures and/or the second opposing spacer structures comprise one or more of:
a silicon nitride material,
a silicon dioxide material,
a silicon carbide material, or
an aluminum oxide material.

9. The device of claim 7, wherein the second opposing spacer structures are on edge regions of a dielectric layer above the second electrode layer.

10. The device of claim 9, wherein the edge regions of the dielectric layer above the second electrode layer overhang the first opposing end surfaces.

11. The device of claim 7, further comprising:
a connection structure between the first opposing spacer structures and between the second opposing spacer structures.

12. The device of claim 11, further comprising:
a dielectric material,
wherein the dielectric material is between the connection structure and the first opposing spacer structures, and
wherein the dielectric material is between the connection structure and the second opposing spacer structures.

13. The device of claim 12, wherein a portion of the second opposing spacer structures are over a portion of the first opposing spacer structures.

14. A method, comprising:
forming, from a side-view perspective, a stair-shaped cavity region that extends vertically into a layer stack comprising electrode layers interspersed with dielectric layers;
forming, in ends of the electrode layers that are exposed through the stair-shaped cavity region, recesses that extend laterally into the electrode layers;
forming, along contours of the stair-shaped cavity region and within the recesses, a dielectric layer; and
removing portions of the dielectric layer to form spacer structures adjacent to the ends of the electrode layers.

15. The method of claim 14, wherein forming the recesses that extend laterally into the electrode layers comprises:
performing an etching operation to laterally etch a material of the electrode layers to form the recesses.

16. The method of claim 15, wherein performing the etching operation comprises:
performing a wet-etching operation in which a hydrogen peroxide fluid is used to selectively etch the material of the electrode layers,
wherein the material of the electrode layers includes a titanium nitride material.

17. The method of claim 14, wherein forming the recesses that extend laterally into the electrode layers comprises:
forming edge regions of dielectric layers adjacent to the recesses,
wherein the edge regions comprise a width.

18. The method of claim 17, wherein the width corresponds to a first width and forming the dielectric layer comprises:
forming the dielectric layer to include a second width that, relative to the first width, is greater than or equal to the first width.

19. The method of claim 14, wherein removing the portions of the dielectric layer to form the spacer structures adjacent to the ends of the electrode layers comprises:
removing the portions of the dielectric layer to stagger, horizontally, the spacer structures within the stair-shaped cavity region,
wherein the stagger is based on respective depths of the spacer structures within the stair-shaped cavity region.

20. The method of claim 14, further comprising:
forming one or more dielectric layers that fill the stair-shaped cavity region; and
forming a connection structure through the one or more dielectric layers and between the spacer structures,
wherein forming the connection structure through the one or more dielectric layers and between the spacer structures reduces a likelihood of electrical shorting between one or more of the electrode layers through the connection structure.
